(19) United States
(12) Patent Application Publication
(10) Pub. No.: US 2022/0302678 A1
(43) Pub. Date: Sep. 22, 2022

(54) SEMICONDUCTOR LASERS

(71) Applicant: MACOM Technology Solutions Holdings, Inc., Lowell, MA (US)

(72) Inventors: Yifan Jiang, Newfield, NY (US); Malcolm R. Green, Lansing, NY (US); Wolfgang Parz, Ithaca, NY (US); Lihua Hu, Ithaca, NY (US)

(73) Assignee: MACOM Technology Solutions Holdings, Inc., Lowell, MA (US)

(21) Appl. No.: 17/204,550

(22) Filed: Mar. 17, 2021

(51) Int. Cl. H01S 5/12; H01S 5/028

(52) U.S. Cl. CPC H01S 5/124; H01S 5/0287

(57) ABSTRACT

Semiconductors lasers are disclosed having an active region having a longitudinal axis, a first facet end, and a second facet end. The second facet end emitting the main output beam of light from of the respective semiconductor laser. The first facet end may have a low-reflection coating. The first facet end may be non-perpendicular to the longitudinal axis of the active region. The semiconductor lasers may be distributed feedback (DFB) lasers having a plurality of diffraction gratings along the longitudinal axis of the active region. The plurality of diffraction grating may include a first diffraction grating positioned proximate the first end of the active region, a second diffraction grating positioned proximate the second end of the active region, and a third diffraction grating positioned between the first diffraction grating and the second diffraction grating. The first diffraction grating may be spaced apart from the third diffraction grating along the longitudinal axis of the active region by a first distance. The second diffraction grating may be spaced apart from the third diffraction grating along the longitudinal axis of the active region by a second distance. Each of the first distance and the second distance being greater than zero.

### FIELD

The present disclosure relates to semiconductor lasers and in particular to distributed feedback (DFB) semiconductor lasers having a plurality of gratings.

### BACKGROUND

Referring to FIG. 1, a conventional semiconductor laser 10 having a plurality of distributed feedback (DFB) gratings 12 is represented. Conventional semiconductor laser 10 includes an active layer 14, an n-type cladding layer 16, and a p-type cladding layer 18. Active layer 14 has a longitudinal axis 20. Active layer 14 is bounded in a longitudinal direction by a rear facet 30 and a front facet 32. Rear facet 30 has a high-reflectivity coating provided thereon. Exemplary high-reflectivity coatings reflect 50% or more of incident light. Front facet 32 has a low-reflectivity coating provided thereon. Exemplary low-reflectivity coatings reflect less than 5% of incident light.

The plurality of DFB gratings 12 include a rear standard diffraction grating 40 positioned proximate rear facet 30 and having a longitudinal length 42, a front standard diffraction grating 44 positioned proximate front facet 32 and having a longitudinal length 46, and a third grating 48 positioned between rear standard diffraction grating 40 and front standard diffraction grating 44 and having a longitudinal length 50. Rear standard diffraction grating 40 and third grating 48 are separated by region 52 and front standard diffraction grating 44 and third grating 48 are separated by region 54. Each of regions 52 and 54 do not include any grating structure. For example, each of regions 52 and 54 may be comprised of the p-type cladding layer material and be void of any grating structure. In another example, each of regions 52 and 54 may include a block of material different than the p-type cladding layer material and also void of any grating structure. As such, rear standard diffraction grating 40 and third grating 48 are non-contiguous and third grating 48 and front standard diffraction grating 44 are non-contiguous. The third grating 48 has a different pitch than rear standard diffraction grating 40 and front standard diffraction grating 44.

Referring to FIG. 2, the longitudinal length of active layer 14 is about 150 microns (μm), the longitudinal length 42 of rear standard diffraction grating 40 is about 25 μm, the longitudinal length 46 of front standard diffraction grating 44 is about 75 μm, and the longitudinal length 50 of the third grating 48 is about 50 μm. It should be understood that the longitudinal lengths of regions 52 and 54 are about 100 nanometers (nm) or 300 nm and are not represented in FIG. 2.

Semiconductor laser 10 has an active layer made of III-V material, an n-type cladding layer 16 made of III-V material, and a p-type cladding layer 18 made of III-V material. The pitch of rear standard diffraction grating 40 is around 200 nm.

### SUMMARY

In an exemplary embodiment of the present disclosure, a semiconductor laser is provided. The semiconductor laser comprising an active region having a longitudinal axis, a first facet end and a second facet end, the second facet end emitting an output beam of light from the semiconductor laser; a first low-reflection coating provided on the first facet end of the active region; a second low-reflection coating provided on the second facet end of the active region; and a plurality of diffraction gratings positioned along the longitudinal axis of the active region. The plurality of diffraction grating including a first diffraction grating positioned proximate the first facet end of the active region, a second diffraction grating positioned proximate the second facet end of the active region, and a third diffraction grating positioned between the first diffraction grating and the second diffraction grating, the first diffraction grating being spaced apart from the third diffraction grating along the longitudinal axis of the active region by a first distance and the second diffraction grating being spaced apart from the third diffraction grating along the longitudinal axis of the active region by a second distance, each of the first distance and the second distance being greater than zero.

In an example thereof, a mid-point of the third diffraction grating along the longitudinal axis of the active region is positioned closer to the second facet end of the active region than the first facet end of the active region. In a variation thereof, the mid-point of the third diffraction grating is positioned along the longitudinal axis of the active region at about 60% of a length of the active region from the first facet end. In another variation thereof, the third diffraction grating includes a first end and a second end spaced apart along the longitudinal axis of the active region, the second end of the third diffraction grating is positioned along the longitudinal axis of the active region more than two times farther from the second facet end of the active region than the first end of the third diffraction grating from the second facet end of the active region. In a further variation thereof, the mid-point of the third diffraction grating is positioned along the longitudinal axis of the active region at least 40% of a separation from the first facet end to the overall length from the first facet end to the second facet end.

In another example thereof, a mid-point of the third diffraction grating is positioned along the longitudinal axis of the active region in a range of about 30% to about 70% of a separation from the first facet end to an overall length from the first facet end to the second facet end.

In a further example thereof, the third diffraction grating includes a first end and a second end spaced apart along the longitudinal axis of the active region, the second end of the third diffraction grating is positioned along the longitudinal axis of the active region more than two times farther from the second facet end of the active region than the first end of the third diffraction grating from the second facet end of the active region.

In still another example thereof, a mid-point of the third diffraction grating is positioned along the longitudinal axis of the active region at least 40% of a separation from the first facet end to an overall length from the first facet end to the second facet end.

In yet another example thereof, each of the first diffraction grating has a first constant pitch and the second diffraction grating has a second constant pitch. In a variation thereof, the first constant pitch is equal to the second constant pitch.

In still a further example thereof, a mid-point of the third diffraction grating is positioned along the longitudinal axis of the active region at least 47% of a separation from the first facet end to an overall length from the first facet end to the second facet end.

In yet a further example thereof, a mid-point of the third diffraction grating is positioned along the longitudinal axis of the active region at least 53% of a separation from the first facet end to an overall length from the first facet end to the second facet end.

In yet still a further example thereof, a mid-point of the third diffraction grating is positioned along the longitudinal axis of the active region at least 60% of a separation from the first facet end to an overall length from the first facet end to the second facet end.

In a further still example thereof, the third diffraction grating is a corrugation-pitch-modulated diffraction grating.

In yet a further still example thereof, the third diffraction grating is a quarter wave shifting grating structure.

In another exemplary embodiment thereof, a semiconductor laser is provided. The semiconductor laser comprising an active region having a longitudinal axis, a first facet end and a second facet end, the first facet end being non-perpendicular to the longitudinal axis and the second facet end emitting an output beam of the semiconductor laser; a first low-reflection coating provided on the second facet end of the active region; and a plurality of diffraction gratings positioned along the longitudinal axis of the active region. The plurality of diffraction grating including a first diffraction grating positioned proximate the first end of the active region, a second diffraction grating positioned proximate the second end of the active region, and a third diffraction grating positioned between the first diffraction grating and the second diffraction grating, the first diffraction grating being spaced apart from the third diffraction grating along the longitudinal axis of the active region by a first distance and the second diffraction grating being spaced apart from the third diffraction grating along the longitudinal axis of the active region by a second distance, each of the first distance and the second distance being greater than zero.

In an example thereof, a mid-point of the third diffraction grating along the longitudinal axis of the active region is positioned closer to the second facet end of the active region than the first facet end of the active region.

In another example thereof, a mid-point of the third diffraction grating is positioned along the longitudinal axis of the active region in a range of about 30% to about 70% of a separation from the first facet end to an overall length from the first facet end to the second facet end. In a variation thereof, the mid-point of the third diffraction grating is positioned along the longitudinal axis of the active region at about 60% of a length of the active region from the first facet end. In another variation thereof, the third diffraction grating includes a first end and a second end spaced apart along the longitudinal axis of the active region, the second end of the third diffraction grating is positioned along the longitudinal axis of the active region more than two times farther from the second facet end of the active region than the first end of the third diffraction grating from the second facet end of the active region. In still another variation thereof, the mid-point of the third diffraction grating is positioned along the longitudinal axis of the active region at least 40% of a separation from the first facet end to the overall length from the first facet end to the second facet end.

In a further example thereof, the third diffraction grating includes a first end and a second end spaced apart along the longitudinal axis of the active region, the second end of the third diffraction grating is positioned along the longitudinal axis of the active region more than two times farther from the second facet end of the active region than the first end of the third diffraction grating from the second facet end of the active region.

In yet a further example thereof, a mid-point of the third diffraction grating is positioned along the longitudinal axis of the active region at least 40% of a separation from the first facet end to an overall length from the first facet end to the second facet end.

In still a further example thereof, each of the first diffraction grating has a first constant pitch and the second diffraction grating has a second constant pitch. In a variation thereof, the first constant pitch is equal to the second constant pitch.

In a further still example thereof, a mid-point of the third diffraction grating is positioned along the longitudinal axis of the active region at least 47% of a separation from the first facet end to an overall length from the first facet end to the second facet end.

In yet a further still example thereof, a mid-point of the third diffraction grating is positioned along the longitudinal axis of the active region at least 53% of a separation from the first facet end to an overall length from the first facet end to the second facet end.

In another still example thereof, a mid-point of the third diffraction grating is positioned along the longitudinal axis of the active region at least 60% of a separation from the first facet end to an overall length from the first facet end to the second facet end.

In yet another still example thereof, the semiconductor laser further comprising a second low-reflection coating provided on the first facet end of the active region.

In another example thereof, the third diffraction grating is a corrugation-pitch-modulated diffraction grating.

In a further example thereof, the third diffraction grating is a quarter wave shifting grating structure.

### BRIEF DESCRIPTION OF THE DRAWINGS

The above-mentioned and other features and advantages of this disclosure, and the manner of attaining them, will become more apparent and will be better understood by reference to the following description of exemplary embodiments taken in conjunction with the accompanying drawings, wherein:

FIG. 1 illustrates a representative view of a conventional distributed feedback semiconductor laser including a plurality of gratings spaced along a longitudinal axis of the active region;

FIG. 2 illustrates a representative view of the respective lengths of each diffraction grating of the plurality of diffraction gratings of the conventional distributed feedback semiconductor laser of FIG. 1;

FIG. 3 illustrates a representative side view of an exemplary distributed feedback semiconductor laser of the present disclosure including a plurality of gratings spaced along a longitudinal axis of the active region and including a low-reflective coating on the front facet and a low-reflective coating on the rear facet;

FIG. 4 illustrates a representative top of the exemplary distributed feedback semiconductor laser of FIG. 3;

FIG. 5 illustrates a representative side view of an exemplary distributed feedback semiconductor laser of the present disclosure including a plurality of gratings spaced along a longitudinal axis of the active region and including a low-reflective coating on the front facet and an angled uncoated rear facet angled in the y-z plane;

FIG. 6 illustrates a representative top of the exemplary distributed feedback semiconductor laser of FIG. 5 with the angled uncoated rear facet in the x-y plane instead of the y-z plane shown in FIG. 5;

FIG. 7 illustrates a representative side view of an exemplary distributed feedback semiconductor laser of the present disclosure including a plurality of gratings spaced along a longitudinal axis of the active region and including a low-reflective coating on the front facet, a low-reflective coating on the rear facet, the rear facet being angled in the y-z plane;

FIG. 8 illustrates a representative view of another exemplary distributed feedback semiconductor laser of the present disclosure including a plurality of gratings spaced along a longitudinal axis of the active region including a grating having a reduced kappa by the drop grating methodology;

FIG. 9 illustrates a representative view of a first example of the respective lengths of each diffraction grating of the plurality of diffraction gratings of the exemplary distributed feedback semiconductor laser of FIG. 3;

FIG. 10 illustrates a representative view of a second example of the respective lengths of each diffraction grating of the plurality of diffraction gratings of the exemplary distributed feedback semiconductor laser of FIG. 3;

FIG. 11 illustrates a representative view of a third example of the respective lengths of each diffraction grating of the plurality of diffraction gratings of the exemplary distributed feedback semiconductor laser of FIG. 3;

FIG. 12 illustrates a representative view of a fourth example of the respective lengths of each diffraction grating of the plurality of diffraction gratings of the exemplary distributed feedback semiconductor laser of FIG. 3;

FIG. 13 illustrates a representative view of a fifth example of the respective lengths of each diffraction grating of the plurality of diffraction gratings of the exemplary distributed feedback semiconductor laser of FIG. 3; and

FIG. 14 illustrates a comparison of the overall yield percentage of devices of the examples provided in FIGS. 4-8 satisfying a side mode suppression ratio threshold compared to the conventional distributed feedback semiconductor laser of FIG. 2 at multiple temperatures.

Corresponding reference characters indicate corresponding parts throughout the several views. The exemplification set out herein illustrates an exemplary embodiment of the invention and such exemplification is not to be construed as limiting the scope of the invention in any manner.

### DETAILED DESCRIPTION OF THE DRAWINGS

For the purposes of promoting an understanding of the principles of the present disclosure, reference is now made to the embodiments illustrated in the drawings, which are described below. The embodiments disclosed herein are not intended to be exhaustive or limit the present disclosure to the precise form disclosed in the following detailed description. Rather, the embodiments are chosen and described so that others skilled in the art may utilize their teachings. Therefore, no limitation of the scope of the present disclosure is thereby intended. Corresponding reference characters indicate corresponding parts throughout the several views.

The terms “couples”, “coupled”, “coupler” and variations thereof are used to include both arrangements wherein the two or more components are in direct physical contact and arrangements wherein the two or more components are not in direct contact with each other (e.g., the components are “coupled” via at least a third component), but yet still cooperate or interact with each other.

Unless otherwise indicated, all numbers expressing feature sizes, amounts, and physical properties used in the specification and claims are to be understood as being modified in all instances by the term “about.” Accordingly, unless indicated to the contrary, the numerical parameters set forth in the foregoing specification and attached claims are approximations that can vary depending upon the desired properties sought to be obtained by those skilled in the art utilizing the teachings disclosed herein.

In some instances throughout this disclosure and in the claims, numeric terminology, such as first, second, third, and fourth, is used in reference to various components or features. Such use is not intended to denote an ordering of the components or features. Rather, numeric terminology is used to assist the reader in identifying the component or features being referenced and should not be narrowly interpreted as providing a specific order of components or features.

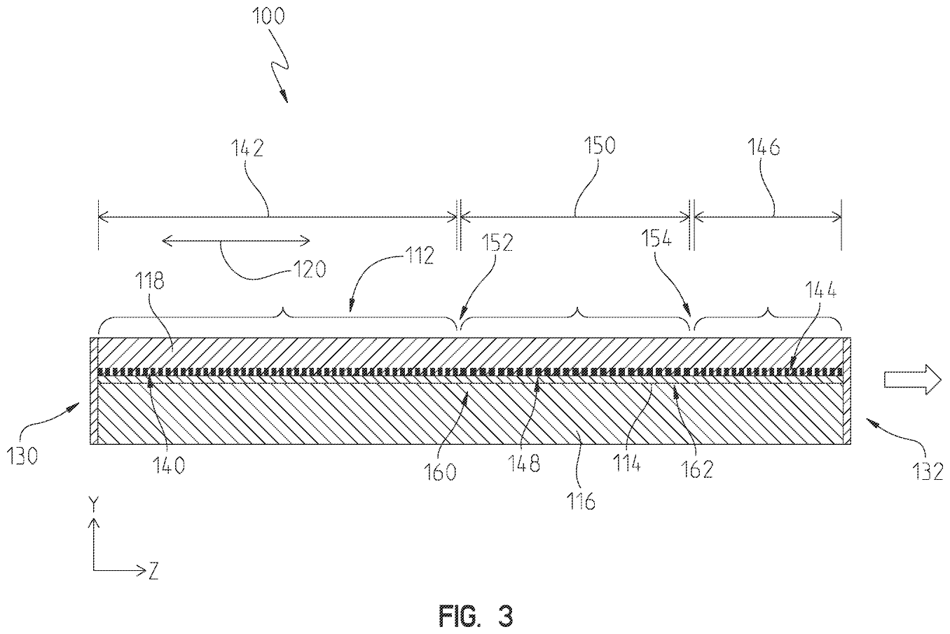

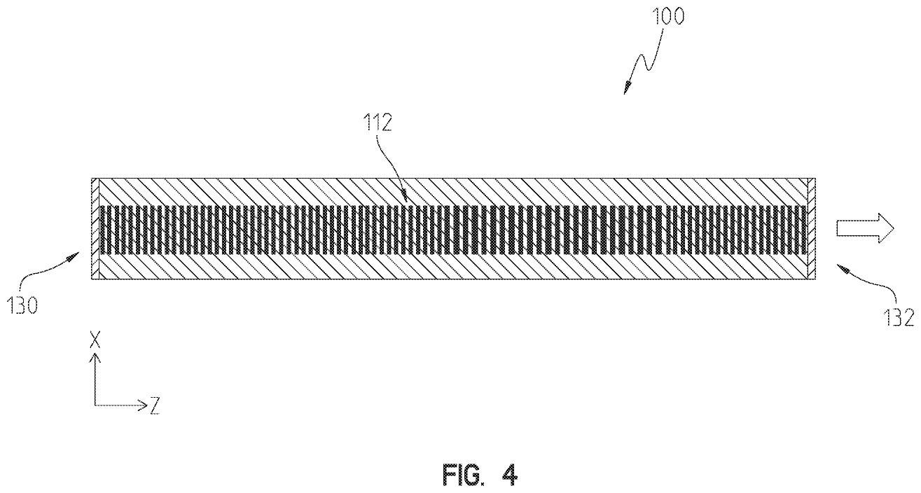

Referring to FIG. 3 a side view of an exemplary semiconductor laser 100 having a plurality of distributed feedback (DFB) gratings 112 is represented. FIG. 4 illustrates a top view of semiconductor laser 100. Semiconductor laser 100 includes an active layer 114, an n-type cladding layer 116, and a p-type cladding layer 118. Active layer 114 has a longitudinal axis 120. Active layer 114 is bounded in a longitudinal direction by a rear facet 130 and a front facet 132. In embodiments, n-type cladding layer 116 is positioned below active layer 114 and p-type cladding layer 118 is positioned above active layer 114.

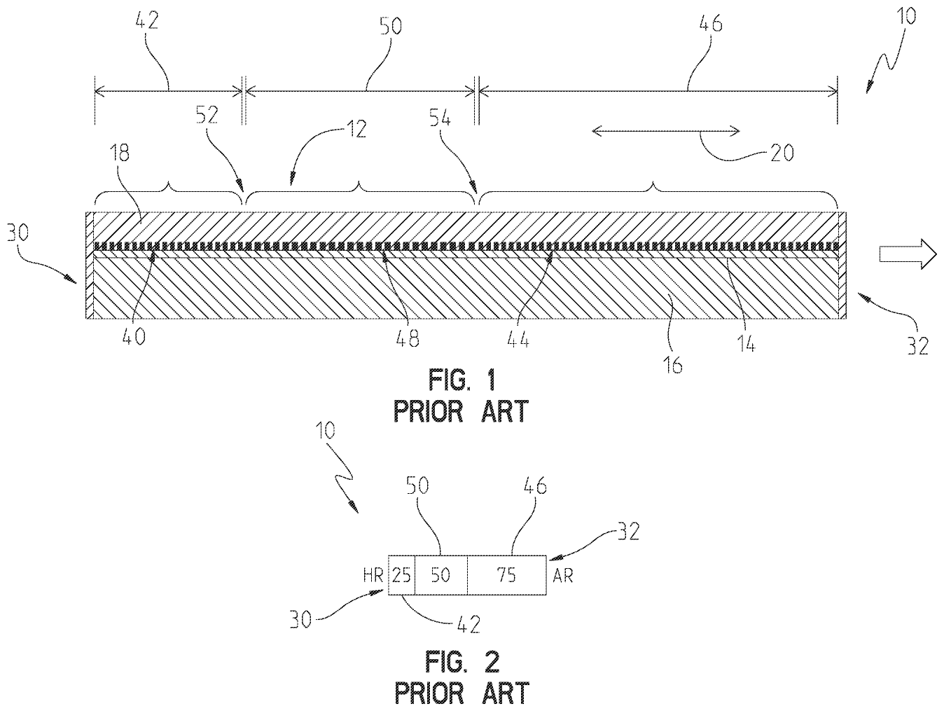

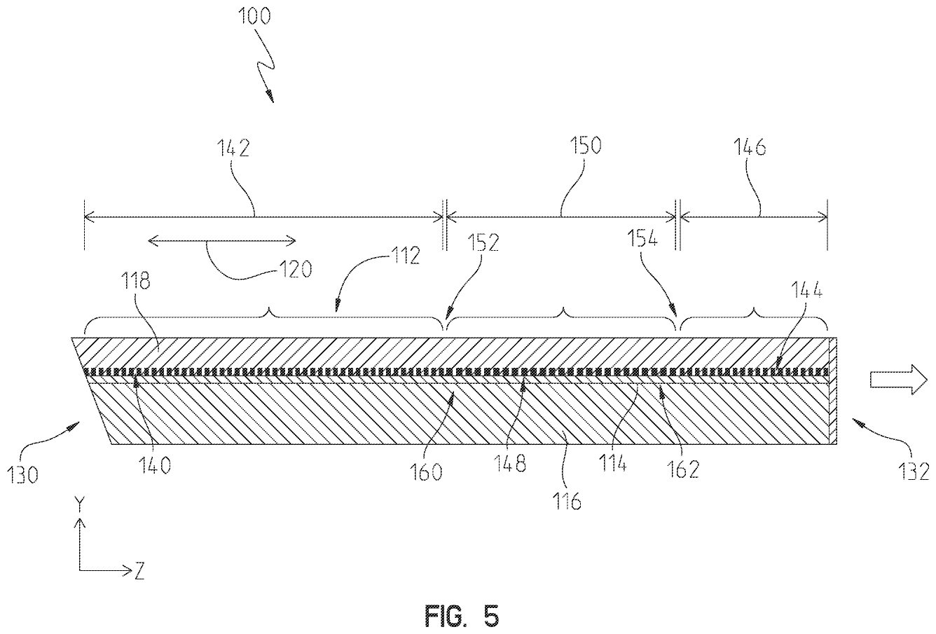

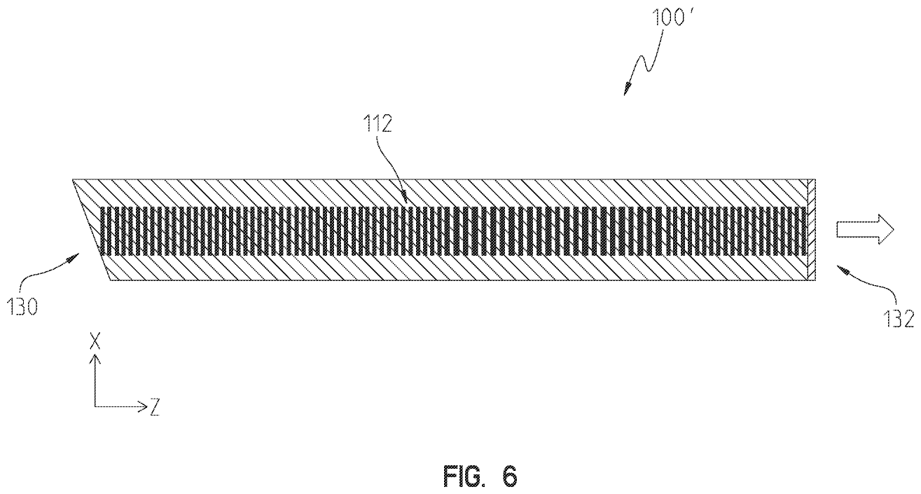

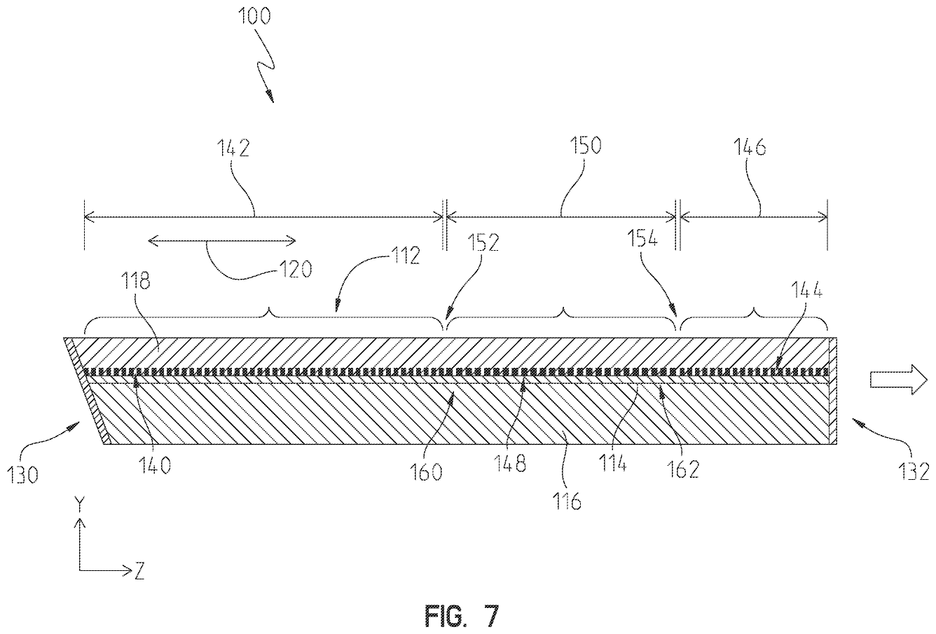

Front facet 132 has a low-reflectivity coating provided thereon. Exemplary low-reflectivity coatings reflect up to about 5% of incident light. In the embodiment shown in FIGS. 3 and 4, rear facet 130 has a low-reflectivity coating provided thereon and rear facet is normal to longitudinal axis 120 of semiconductor laser 100. Exemplary low-reflectivity coatings reflect up to about 5% of incident light. Referring to FIGS. 5 and 6, other embodiments of semiconductor laser 100′ are shown wherein rear facet 130 is uncoated and angled relative to longitudinal axis 120 of semiconductor laser 100. In the example illustrated in FIG. 5, rear facet 130 is angled in the Y-Z plane. In the example illustrated in FIG. 6, rear facet 130 is angled in the X-Y plane. Referring to FIG. 7 another embodiment of semiconductor laser 100″ is shown wherein rear facet 130 has a low-reflectivity coating provided thereon and is angled relative to longitudinal axis 120 of semiconductor laser 100 in the Y-Z plane. Exemplary low-reflectivity coatings reflect up to about 5% of incident light. Either the use of a low-reflectivity coating or an angled facet may remove the facet phase impact on device SMSR yield and reduce slope variations across operating temperatures of semiconductor laser 100, 100′, 100″ compared to high-reflectivity coating of the conventional semiconductor laser 10 of FIG. 1.

Returning to FIGS. 3 and 4, the plurality of DFB gratings 112 include a rear standard diffraction grating 140 positioned proximate rear facet 130 and having a longitudinal length 142, a front standard diffraction grating 144 positioned proximate front facet 132 and having a longitudinal length 146, and a third grating 148 positioned between rear standard diffraction grating 140 and front standard diffraction grating 144 and having a longitudinal length 150.

Rear standard diffraction grating 140 and grating 148 are separated by region 152 and front standard diffraction grating 144 and grating 148 are separated by region 154. Each of regions 152 and 154 do not include any grating structure. For example, each of regions 152 and 154 may be comprised of the p-type cladding layer material and be void of any grating structure. In another example, each of regions 152 and 154 may include a block of material different than the p-type cladding layer material and also void of any grating structure. As such, rear standard diffraction grating 140 and grating 148 are non-contiguous and grating 148 and front standard diffraction grating 144 are non-contiguous. In the illustrated embodiments, grating 148 is a corrugation-pitch-modulated (CPM) diffraction grating.

In embodiments, grating 148 is a quarter wave shifting (QWS) grating structure. The quarter wave shifting grating structure includes a first grating region and a second grating region, each having a constant grating pitch and depth. The first grating region and the second grating region are joined with a phase jump of n at the interface between the first grating structure and the second grating structure. In embodiments, with the quarter wave shifting grating structure instead of the CPM structure of grating 148, region 152 and region 154 may be eliminated. In embodiments, region 152 and region 154 are maintained with the quarter wave shifting grating structure instead of the CPM structure of grating 148.

Semiconductor laser 100 may have a ridge waveguide structure, such as shown in FIG. 4 and FIG. 6, or a buried heterostructure structure. Exemplary materials for n-type cladding layer 116 include III-V material. Exemplary materials for p-type cladding layer 118 include III-V material. Exemplary materials for active layer 114 include III-V material.

Referring to FIG. 3, rear standard diffraction grating 140 has a constant pitch. In embodiments, the constant pitch is about 200 nanometers (nm) although longer or shorter pitches may be implemented. In embodiments, rear diffraction grating 140 may be a chirped grating having a non-constant pitch. In embodiments, front standard diffraction grating 144 has a constant pitch. In embodiments, the constant pitch is about 200 nanometers (nm) although longer or shorter pitches may be implemented. In embodiments, front diffraction grating 144 may be a chirped grating having a non-constant pitch. In embodiments, the pitch of rear standard diffraction grating 140 equals the pitch of front standard diffraction grating 144. In embodiments, the pitch of rear standard diffraction grating 140 is non-equal to the pitch of front standard diffraction grating 144. In embodiments, the pitch of grating 148 is less than the pitch of rear standard diffraction grating 140 and the pitch of front standard diffraction grating 144. In embodiments, the pitch of grating 148 is greater than the pitch of rear standard diffraction grating 140 and the pitch of front standard diffraction grating 144.

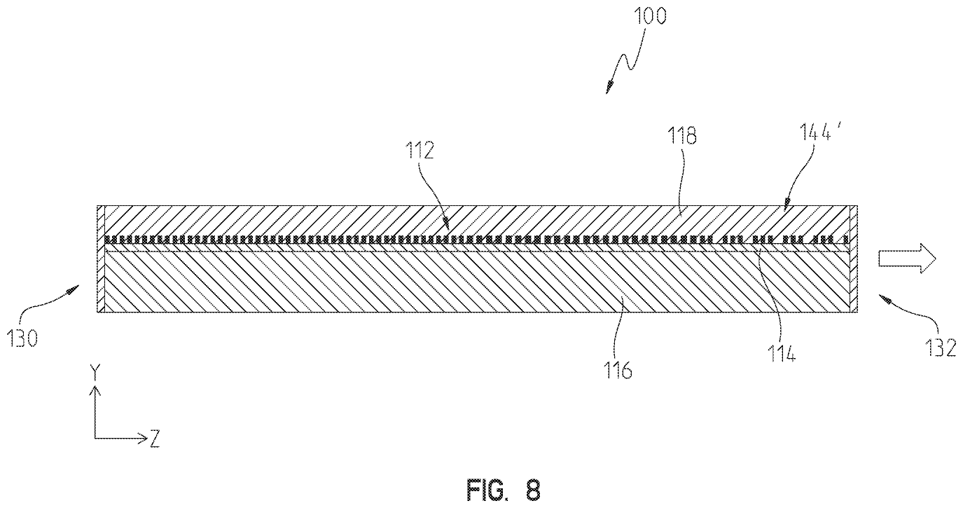

Turning to FIG. 8, another embodiment of laser 100 is shown. Front diffraction grating 144′ has a reduced grating strength by the drop grating pitch method wherein, the grating 144′ is missing portions of the periodic grating structure. In embodiments, the grating strength of one or more portions of the plurality of DFB gratings 112 may be reduced to tailor the power distribution along longitudinal axis 120 of laser 100. In embodiments, one or sections of the plurality of DFB gratings 112 may be either a uniform grating or a chirped grating.

FIGS. 9-13 illustrate various exemplary embodiments of laser 100. Although all of the illustrated embodiments have overall lengths of about 150 microns (μm), but shorter or longer length lasers may be produced. Further, all of illustrated embodiments have a length of grating 148 of about 50 μm, but shorter or longer length of grating 148 may be produced. In addition or alternatively, the mid-point of grating 148 may move towards rear facet 130 or front facet 132, such as in the range of about 30% to about 70%. For example, in a 150 μm length laser 100, the mid-point of grating 148 may be about 45 μm from rear facet 130 (about 30%) to about 105 μm from the rear facet (about 70%).

Referring to FIG. 9, an example of the laser 100 of FIG. 3 is provided. The longitudinal length of active layer 114 is about 150 microns (μm), the longitudinal length 142 of rear standard diffraction grating 140 is about 65 μm, the longitudinal length 146 of front standard diffraction grating 144 is about 35 μm, and the longitudinal length 150 of grating 148 is about 50 μm. Rear facet 130 and front facet 132 each have a low reflectivity coating provided thereon. In embodiments, rear facet 130 is normal to a longitudinal axis of active layer 114 and has a low reflectivity coating provided thereon. In embodiments, rear facet 130 is angled relative to a longitudinal axis of active layer 114 and has a low reflectivity coating provided thereon. In embodiments, rear facet 130 is angled relative to a longitudinal axis of active layer 114 and is uncoated.

Referring to FIG. 10, an example of the laser 100 of FIG. 3 is provided. The longitudinal length of active layer 114 is about 150 microns (μm), the longitudinal length 142 of rear standard diffraction grating 140 is about 55 μm, the longitudinal length 146 of front standard diffraction grating 144 is about 45 μm, and the longitudinal length 150 of grating 148 is about 50 μm. Rear facet 130 and front facet 132 each have a low reflectivity coating provided thereon. In embodiments, rear facet 130 is normal to a longitudinal axis of active layer 114 and has a low reflectivity coating provided thereon. In embodiments, rear facet 130 is angled relative to a longitudinal axis of active layer 114 and has a low reflectivity coating provided thereon. In embodiments, rear facet 130 is angled relative to a longitudinal axis of active layer 114 and is uncoated.

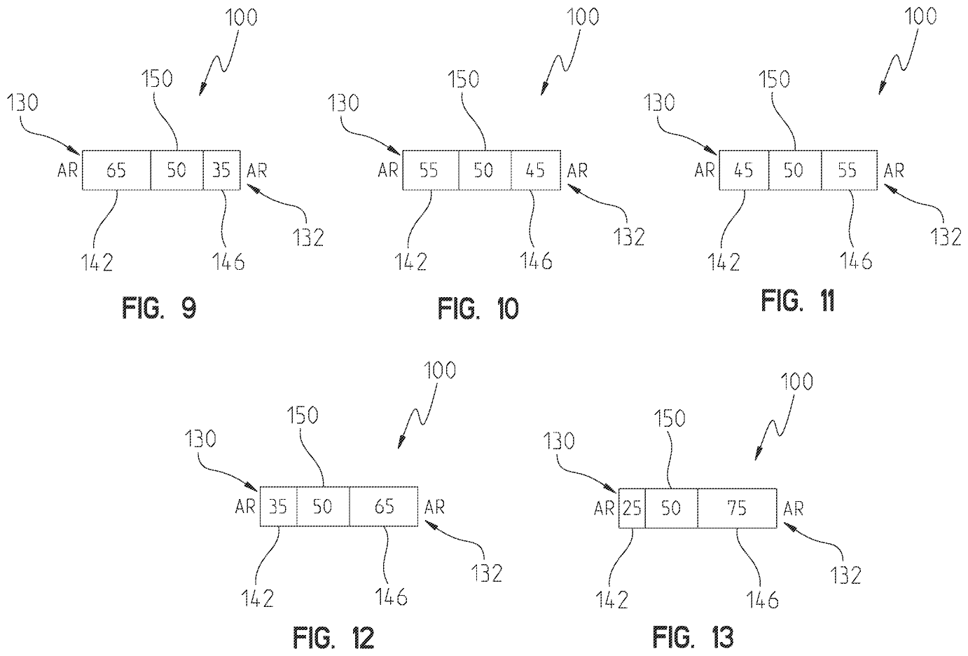

Referring to FIG. 11, an example of the laser 100 of FIG. 3 is provided. The longitudinal length of active layer 114 is about 150 microns (μm), the longitudinal length 142 of rear standard diffraction grating 140 is about 45 μm, the longitudinal length 146 of front standard diffraction grating 144 is about 55 μm, and the longitudinal length 150 of t grating 148 is about 50 μm. Rear facet 130 and front facet 132 each have a low reflectivity coating provided thereon. In embodiments, rear facet 130 is normal to a longitudinal axis of active layer 114 and has a low reflectivity coating provided thereon. In embodiments, rear facet 130 is angled relative to a longitudinal axis of active layer 114 and has a low reflectivity coating provided thereon. In embodiments, rear facet 130 is angled relative to a longitudinal axis of active layer 114 and is uncoated.

Referring to FIG. 12, an example of the laser 100 of FIG. 3 is provided. The longitudinal length of active layer 114 is about 150 microns (μm), the longitudinal length 142 of rear standard diffraction grating 140 is about 35 μm, the longitudinal length 146 of front standard diffraction grating 144 is about 65 μm, and the longitudinal length 150 of grating 148 is about 50 μm. Rear facet 130 and front facet 132 each have a low reflectivity coating provided thereon. In embodiments, rear facet 130 is normal to a longitudinal axis of active layer 114 and has a low reflectivity coating provided thereon. In embodiments, rear facet 130 is angled relative to a longitudinal axis of active layer 114 and has a low reflectivity coating provided thereon. In embodiments, rear facet 130 is angled relative to a longitudinal axis of active layer 114 and is uncoated.

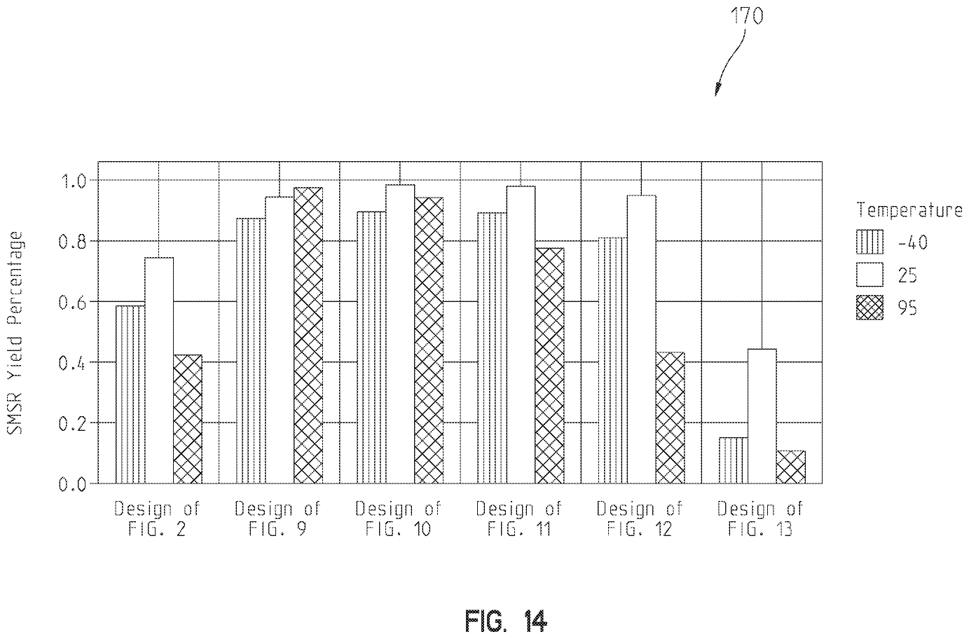

Referring to FIG. 13, an example of the laser 100 of FIG. 3 is provided. The longitudinal length of active layer 114 is about 150 microns (μm), the longitudinal length 142 of rear standard diffraction grating 140 is about 25 μm, the longitudinal length 146 of front standard diffraction grating 144 is about 65 μtm, and the longitudinal length 150 of grating 148 is about 50 μm. Rear facet 130 and front facet 132 each have a low reflectivity coating provided thereon. In embodiments, rear facet 130 is normal to a longitudinal axis of active layer 114 and has a low reflectivity coating provided thereon. In embodiments, rear facet 130 is angled relative to a longitudinal axis of active layer 114 and has a low reflectivity coating provided thereon. In embodiments, rear facet 130 is angled relative to a longitudinal axis of active layer 114 and is uncoated.

The corresponding values of longitudinal length 142, longitudinal length 146, and longitudinal length 150 of the examples provided in FIGS. 9-13 are provided in Table 1. A percentage of longitudinal length 142, longitudinal length 146, and longitudinal length 150 relative to the length of active layer 114 are provided in Table 2. The percentages of a rear edge, a front edge, and a mid-point of grating 148, each relative to a distance to rear facet 130 are provided in Table 3.

TABLE 1
Grating Length (μm)

| | Longitudinal | Longitudinal | Longitudinal |
|---|---|---|---|
| | Length 142 | Length 150 | Length 146 |
| FIG. 9 | 65 | 50 | 35 |
| FIG. 10 | 55 | 50 | 45 |
| FIG. 11 | 45 | 50 | 55 |
| FIG. 12 | 35 | 50 | 65 |
| FIG. 13 | 25 | 50 | 75 |

TABLE 2
Percentage of Active Region Length

| | Longitudinal | Longitudinal | Longitudinal |
|---|---|---|---|
| | Length 142 | Length 150 | Length 146 |
| FIG. 9 | 43% | 33% | 23% |
| FIG. 10 | 37% | 33% | 30% |
| FIG. 11 | 30% | 33% | 37% |
| FIG. 12 | 23% | 33% | 43% |
| FIG. 13 | 17% | 33% | 50% |

TABLE 3
Percentage of Cavity Length for ACPM Section from the
Rear Facet of Laser

| | Back Edge 160 | Mid-Point | Front Edge 162 |
|---|---|---|---|
| | of grating 148 | of grating 148 | of grating 148 |
| FIG. 9 | 43% | 60% | 77% |
| FIG. 10 | 37% | 53% | 70% |
| FIG. 11 | 30% | 47% | 63% |
| FIG. 12 | 23% | 40% | 57% |
| FIG. 13 | 17% | 33% | 50% |

In embodiments, a mid-point of grating 148 along longitudinal axis 120 of active region 114 is positioned closer to facet end 132 of active region 114 than facet end 130 of active region 114. In embodiments, the mid-point of grating 148 may be positioned along longitudinal axis 120 of active region 114 from the rear facet 130 in the range of about 30% to about 70%. In embodiments, the mid-point of grating 148 may be positioned along longitudinal axis 120 of active region 114 from the rear facet 130 in the range of about 33% to about 60%.

In embodiments, a back end 160 of grating 148 may be positioned along longitudinal axis 120 of active region 114 more than two times farther from facet end 132 of active region 114 than a front end 162 of grating 148 from facet end 132 of active region 114. In embodiments, front end 162 of grating 148 may be positioned along longitudinal axis 120 of active region 114 at up to about 37% of an overall longitudinal length of active region 114 from facet end 132.

Referring to FIG. 14, a chart 170 illustrates simulations of the percentage of devices satisfying a side mode suppression ratio (SMSR) yield threshold, such as SMSR>37 dB, for each device of FIGS. 9-13 and FIG. 2 at multiple operating temperatures. The leftmost bar for each device is at an operating temperature of −40° C. The center bar for each device is at an operating temperature of 25° C. The rightmost bar for each device is at an operating temperature of 95° C. As can be seen, the percentage is higher for each of the devices of FIGS. 9-11 at each operating temperature compared to the device of FIG. 2. Further, moving grating section system 148 forward compared to the device of FIG. 2 results in a higher percentage of devices satisfying the SMSR yield threshold for multiple operating temperatures. Thus, the use of a low reflectivity coating for facet end 130 and moving grating section system 148 towards facet end 132 increases the SMSR yield percentage compared to the device of FIG. 2 at the shown operating temperatures. An advantage, among others, of the use of a low reflectivity coating on facet 130 is that it removes the phase shift at facet 130 and the impact of the phase shift on device SMSR yield and laser slope, as shown in FIGS. 14 and 15.

The laser slope for the device of FIG. 9 is higher at 25° C. operating temperature than the device of FIG. 2. Further, the laser slope across the range of −40° C.-95° C. is tighter for the device of FIG. 9 compared to the device of FIG. 2. An advantage, among others, for the tighter slope over the range of temperatures is smaller tracking error for the device of FIG. 9 compared to the device of FIG. 2. The high frequency 3 dB bandwidth (GHz) for each device of FIGS. 9-13 have a wider 3 dB bandwidth than the design of FIG. 2 due generally to lower damping factors.

By replacing the high reflective coating of laser 10 with the low reflectivity coating of laser 100 and/or the angled rear facet of laser 100, it is possible to achieve a near 100% SMSR yield, higher front facet power output, and/or improved high-speed modulation performance based on grating characteristics.

While this invention has been described as having exemplary designs, the present invention can be further modified within the spirit and scope of this disclosure. This application is therefore intended to cover any variations, uses, or adaptations of the invention using its general principles. Further, this application is intended to cover such departures from the present disclosure as come within known or customary practice in the art to which this invention pertains.

We claim:

1. A semiconductor laser, comprising:
an active region having a longitudinal axis, a first facet end and a second facet end, the second facet end emitting an output beam of light from the semiconductor laser;
a first low-reflection coating provided on the first facet end of the active region;
a second low-reflection coating provided on the second facet end of the active region;
a plurality of diffraction gratings positioned along the longitudinal axis of the active region, the plurality of diffraction grating including a first diffraction grating positioned proximate the first facet end of the active region, a second diffraction grating positioned proximate the second facet end of the active region, and a third diffraction grating positioned between the first diffraction grating and the second diffraction grating, the first diffraction grating being spaced apart from the third diffraction grating along the longitudinal axis of the active region by a first distance and the second diffraction grating being spaced apart from the third diffraction grating along the longitudinal axis of the active region by a second distance, each of the first distance and the second distance being greater than zero.

2. The semiconductor laser of claim 1, wherein a mid-point of the third diffraction grating along the longitudinal axis of the active region is positioned closer to the second facet end of the active region than the first facet end of the active region.

3. The semiconductor laser of claim 1, wherein a mid-point of the third diffraction grating is positioned along the longitudinal axis of the active region in a range of about 30% to about 70% of a separation from the first facet end to an overall length from the first facet end to the second facet end.

4. The semiconductor laser of claim 2, wherein the mid-point of the third diffraction grating is positioned along the longitudinal axis of the active region at about 60% of a length of the active region from the first facet end.

5. The semiconductor laser of claim 2, wherein the third diffraction grating includes a first end and a second end spaced apart along the longitudinal axis of the active region, the second end of the third diffraction grating is positioned along the longitudinal axis of the active region more than two times farther from the second facet end of the active region than the first end of the third diffraction grating from the second facet end of the active region.

6. The semiconductor laser of claim 2, wherein the mid-point of the third diffraction grating is positioned along the longitudinal axis of the active region at least 40% of a separation from the first facet end to the overall length from the first facet end to the second facet end.

7. The semiconductor laser of claim 1, wherein the third diffraction grating includes a first end and a second end spaced apart along the longitudinal axis of the active region, the second end of the third diffraction grating is positioned along the longitudinal axis of the active region more than two times farther from the second facet end of the active region than the first end of the third diffraction grating from the second facet end of the active region.

8. The semiconductor laser of claim 1, wherein a mid-point of the third diffraction grating is positioned along the longitudinal axis of the active region at least 40% of a separation from the first facet end to an overall length from the first facet end to the second facet end.

9. The semiconductor laser of claim 1, wherein each of the first diffraction grating has a first constant pitch and the second diffraction grating has a second constant pitch.

10. The semiconductor laser of claim 9, wherein the first constant pitch is equal to the second constant pitch.

11. The semiconductor laser of claim 1, wherein a mid-point of the third diffraction grating is positioned along the longitudinal axis of the active region at least 47% of a separation from the first facet end to an overall length from the first facet end to the second facet end.

12. The semiconductor laser of claim 1, wherein a mid-point of the third diffraction grating is positioned along the longitudinal axis of the active region at least 53% of a separation from the first facet end to an overall length from the first facet end to the second facet end.

13. The semiconductor laser of claim 1, wherein a mid-point of the third diffraction grating is positioned along the longitudinal axis of the active region at least 60% of a separation from the first facet end to an overall length from the first facet end to the second facet end.

14. The semiconductor laser of claim 1, wherein the third diffraction grating is a corrugation-pitch-modulated diffraction grating.

15. The semiconductor laser of claim 1, wherein the third diffraction grating is a quarter wave shifting grating structure.

16. A semiconductor laser, comprising:
an active region having a longitudinal axis, a first facet end and a second facet end, the first facet end being non-perpendicular to the longitudinal axis and the second facet end emitting an output beam of the semiconductor laser;
a first low-reflection coating provided on the second facet end of the active region;
a plurality of diffraction gratings positioned along the longitudinal axis of the active region, the plurality of diffraction grating including a first diffraction grating positioned proximate the first end of the active region, a second diffraction grating positioned proximate the second end of the active region, and a third diffraction grating positioned between the first diffraction grating and the second diffraction grating, the first diffraction grating being spaced apart from the third diffraction grating along the longitudinal axis of the active region by a first distance and the second diffraction grating being spaced apart from the third diffraction grating along the longitudinal axis of the active region by a second distance, each of the first distance and the second distance being greater than zero.

17. The semiconductor laser of claim 16, wherein a mid-point of the third diffraction grating along the longitudinal axis of the active region is positioned closer to the second facet end of the active region than the first facet end of the active region.

18. The semiconductor laser of claim 16, wherein a mid-point of the third diffraction grating is positioned along the longitudinal axis of the active region in a range of about 30% to about 70% of a separation from the first facet end to an overall length from the first facet end to the second facet end.

19. The semiconductor laser of claim 17, wherein the mid-point of the third diffraction grating is positioned along the longitudinal axis of the active region at about 60% of a length of the active region from the first facet end.

20. The semiconductor laser of claim 17, wherein the third diffraction grating includes a first end and a second end spaced apart along the longitudinal axis of the active region, the second end of the third diffraction grating is positioned along the longitudinal axis of the active region more than two times farther from the second facet end of the active region than the first end of the third diffraction grating from the second facet end of the active region.

21. The semiconductor laser of claim 17, the mid-point of the third diffraction grating is positioned along the longitudinal axis of the active region at least 40% of a separation from the first facet end to the overall length from the first facet end to the second facet end.

22. The semiconductor laser of claim 16, wherein the third diffraction grating includes a first end and a second end spaced apart along the longitudinal axis of the active region, the second end of the third diffraction grating is positioned along the longitudinal axis of the active region more than two times farther from the second facet end of the active region than the first end of the third diffraction grating from the second facet end of the active region.

23. The semiconductor laser of claim 16, a mid-point of the third diffraction grating is positioned along the longitudinal axis of the active region at least 40% of a separation from the first facet end to an overall length from the first facet end to the second facet end.

24. The semiconductor laser of claim 16, wherein each of the first diffraction grating has a first constant pitch and the second diffraction grating has a second constant pitch.

25. The semiconductor laser of claim 24, wherein the first constant pitch is equal to the second constant pitch.

26. The semiconductor laser of claim 16, wherein a mid-point of the third diffraction grating is positioned along the longitudinal axis of the active region at least 47% of a separation from the first facet end to an overall length from the first facet end to the second facet end.

27. The semiconductor laser of claim 16, wherein a mid-point of the third diffraction grating is positioned along the longitudinal axis of the active region at least 53% of a separation from the first facet end to an overall length from the first facet end to the second facet end.

28. The semiconductor laser of claim 16, wherein a mid-point of the third diffraction grating is positioned along the longitudinal axis of the active region at least 60% of a separation from the first facet end to an overall length from the first facet end to the second facet end.

29. The semiconductor laser of claim 16, further comprising a second low-reflection coating provided on the first facet end of the active region.

30. The semiconductor laser of claim 16, wherein the third diffraction grating is a corrugation-pitch-modulated diffraction grating.

31. The semiconductor laser of claim 16, wherein the third diffraction grating is a quarter wave shifting grating structure.
